(19) United States
(12) Patent Application Publication
(10) Pub. No.: US 2024/0055366 A1
(43) Pub. Date: Feb. 15, 2024

(54) SPACER FOR CHIPS ON WAFER SEMICONDUCTOR DEVICE ASSEMBLIES

(71) Applicant: Micron Technology, Inc., Boise, ID (US)

(72) Inventors: Brandon P. Wirz, Boise, ID (US); Andrew M. Bayless, Boise, ID (US); Owen R. Fay, Meridian, ID (US)

(21) Appl. No.: 17/888,324

(22) Filed: Aug. 15, 2022

(51) Int. Cl. H01L 23/552; H01L 23/00; H01L 25/065; H01L 21/56

(52) U.S. Cl. CPC H01L 23/552; H01L 24/96; H01L 24/94; H01L 24/32; H01L 25/0657; H01L 21/565; H01L 21/561; H01L 21/563; H01L 21/568; H01L 2224/95001; H01L 24/08; H01L 2224/08145; H01L 2224/32145; H01L 2924/37001; H01L 2924/35121; H01L 2924/3511; H01L 2924/3025; H01L 2225/06524; H01L 2225/06589; H01L 2225/06537; H01L 2924/182; H01L 2924/1811; H01L 2924/183; H01L 2924/186; H01L 2924/1436; H01L 2924/1438; H01L 2924/1431

(57) ABSTRACT

A semiconductor device assembly, including a lower semiconductor die; a stack of upper semiconductor dies disposed over the lower semiconductor die; a conductive package perimeter material surrounding the stack of upper semiconductor dies; and an encapsulant material disposed between sidewalls of the stack of upper semiconductor dies and the conductive package perimeter material, and horizontally extending between the conductive package perimeter material and the lower semiconductor die. A method of forming a plurality of semiconductor assemblies, including stacking a plurality of semiconductor die stacks on a device wafer; disposing a pre-formed spacer assembly structure including a spacer material and a conductive package perimeter material around each of the plurality of semiconductor die stacks; disposing an encapsulant material between the conductive package perimeter material of the pre-formed spacer assembly structure and the corresponding semiconductor die stack; and singulating the device wafer to form the plurality of semiconductor device assemblies.

### TECHNICAL FIELD

The present disclosure generally relates to semiconductor devices, and more particularly relates to spacers for chips on wafer (CoW) semiconductor device assemblies.

### BACKGROUND

Semiconductor packages typically include a semiconductor die (e.g., memory chip, microprocessor chip, imager chip) mounted on a substrate or an interface wafer and encased in a protective covering (e.g., an encapsulating material). The semiconductor die may include functional features, such as memory cells, processor circuits, or imager devices, as well as bond pads electrically connected to the functional features. The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies.

### BRIEF DESCRIPTION OF THE DRAWINGS

FIGS. 1A through 1E illustrate stages of a process for semiconductor device assemblies in accordance with embodiments of the present technology.

FIGS. 2A through 2D depict a spacer assembly for semiconductor device assemblies in accordance with embodiments of the present technology.

FIGS. 3A and 3B illustrate semiconductor device assemblies in accordance with embodiments of the present technology.

FIGS. 4A and 4B illustrate semiconductor device assemblies in accordance with embodiments of the present technology.

FIG. 5 is a flow chart illustrating a method of processing semiconductor device assemblies according to embodiments of the present technology.

FIG. 6 is a flow chart illustrating a method of processing a spacer assembly according to embodiments of the present technology.

FIG. 7 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

CoW assembly is a promising technology for high-density package application to overcome the limitations of Wafer-to-Wafer (WoW) bonding and improve die stacking process yield and bonding placement accuracy. Conventional CoW assembly includes encapsulant material filling for mechanical support and electrical isolation of the semiconductor device assemblies. The filling of encapsulant materials in general is followed by a post mold cure (PMC) process at an elevated temperature so as to cross-link the encapsulant materials for stiffness.

Wafer level molding and post mold cure (PMC) are important process steps in the CoW approach, in which molding materials are applied on the semiconductor assemblies and are cured to fully cross-link the mold compound for stiffness, respectively. The PMC process is generally implemented in the CoW process to ensure suitable levels of mechanical strength are reached through accelerating the molding material curing process and optimizing some physical properties of the molding material by raising ambient temperature. However, there is always a coefficient of thermal expansion (CTE) mismatch between the molding materials and the silicon wafer. During the PMC process, microstructure of the molding materials, e.g., Epoxy molding compound (EMC), can be changed and warpage of the semiconductor assemblies can be formed due to the CTE mismatch. Moreover, the PMC process may cause a high warpage on the CoW assemblies and delaminate the device wafer from the carrier wafer, also affecting downstream packaging process, e.g., packages singulation. The warpage issue may be raised from the CTE mismatch between encapsulant material and semiconductor dies in the CoW assemblies. By adding underfill between these two components to enhance solder joint reliability and encapsulating the CoW device and substrate with EMC to protect the CoW package can make the package warpage even worse, depending on the mechanical and thermo-mechanical properties of the underfill and encapsulant materials, and the relative thickness of each of the components of the CoW assemblies.

To address these challenges and others, the present technology applies a spacer assembly to the CoW assemblies. The spacer assembly includes a grid spacer with a higher CTE and a conductive package perimeter material with a lower CTE. The spacer assembly may be attached to a carrier wafer and the conductive package perimeter can be pressure fitted within the spacer grid of the spacer assembly. In the CoW packaging process, once a plurality of semiconductor dies or die stacks are attached to a device wafer, and the spacer assembly can be disposed on the device wafer and between the plurality of semiconductor dies. After encapsulant material being filled into the CoW assemblies, a stealth dicing process can be conducted, i.e., forming dislocations on the device wafer and aligning to the dislocations to the grid spacer. At an elevated temperature, the spacer grid will expand faster than the conductive package perimeter material, interacting with the semiconductor wafer to break it into semiconductor dies each corresponding to an upper semiconductor die stack. Moreover, the spacer grid can be removed through heating the CoW assemblies and stretching a mount tape on which the CoW assemblies are disposed. These operations create gaps between adjacent semiconductor device assemblies in the CoW packaging in order to relieve stress generated in the PMC process for hardening the encapsulant material and to control the CoW assemblies warpage.

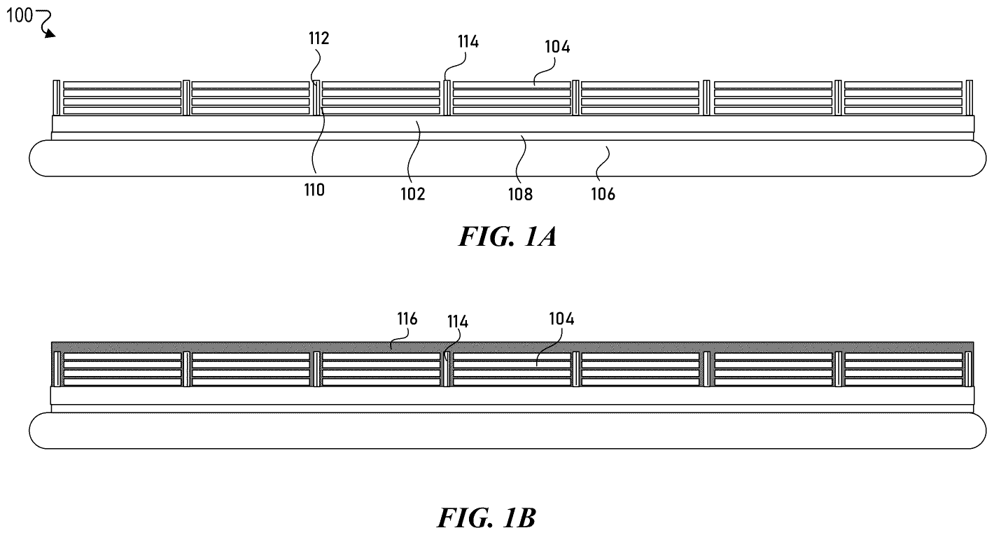

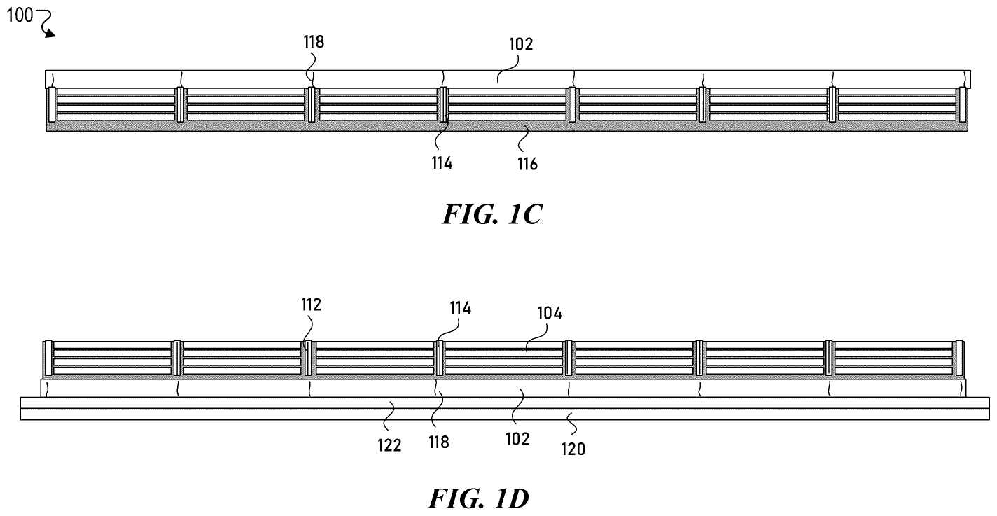

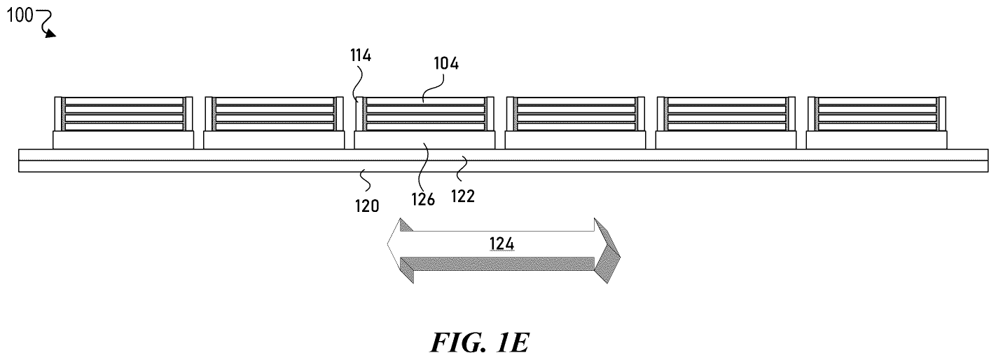

FIGS. 1A through 1E illustrate stages of a processing semiconductor device assemblies 100 in accordance with embodiments of the present technology. FIG. 1A illustrates a cross-sectional view of a CoW assembly having a spacer assembly 110 implemented therein. For example, FIG. 1A shows a plurality of semiconductor die stacks 104 attached to a semiconductor wafer (device wafer) 102. In this example, the semiconductor wafer 102 carrying the plurality of semiconductor die stacks 104 (or semiconductor dies) may be referred to as CoW assembly in view of singulated, individual semiconductor die stacks 104 that are aligned and attached to corresponding interface die of the semiconductor wafer 102. Here, the semiconductor wafer 102 is further attached to a carrier wafer 106 through a bonding layer 108. Specifically, the spacer assembly 110 is disposed within the gaps of the horizontally aligned semiconductor dies 104.

In some embodiments, the spacer assembly 110 may be in a grid shape and include a spacer 112 and a conductive package perimeter material 114. The spacer 112 may be made of at least one of polytetrafluoroethylene (PTFE), organic materials, water-soluble materials, and/or molding materials. In addition, the conductive package perimeter material 114 may be made of conductive metals including copper, tungsten, molybdenum, nickel, titanium, tantalum, platinum, silver, gold, ruthenium, iridium, rhenium, rhodium, or alloys thereof.

As shown in FIG. 1A, the spacer 112 can be disposed in the middle and along a height of the conductive package perimeter material 114 with the spacer assembly 110. The spacer assembly 110 may have the height similar to or slightly shorter than the semiconductor dies 104. In some embodiments, the semiconductor dies may have a height ranging from 200 μm to 1000 μm. Although the present technology is described herein with semiconductor device assemblies including semiconductor dies or a stack of semiconductor dies attached to a semiconductor wafer (e.g., the semiconductor wafer 102), it should be understood that the principles of the present technology are not limited thereto. For example, a semiconductor device assembly in accordance with the present technology may include a single semiconductor die (e.g., a memory die) attached (or bonded) to an interface die.

In some embodiments, the semiconductor wafer 102 includes different types of semiconductor dies (e.g., logic dies, controller dies) than the plurality of semiconductor die stacks 104 (e.g., memory dies, DRAM products) of the stacks. The logic dies of the semiconductor wafer 102 can be configured to exchange electrical signals with the semiconductor dies 104 and with higher level circuitry (e.g., a host device external to the semiconductor device assembly) coupled with the logic dies. In some embodiments, the semiconductor wafer 102 includes interposer dies having various conductive structures (e.g., redistribution layers, vias, interconnects) configured to route electrical signals between the plurality of semiconductor die stacks 104 and higher-level circuitry—e.g., a central processing unit (CPU) coupled with the semiconductor die stacks 104 through the interposer die.

In some embodiments, each of the plurality of semiconductor die stacks 104 may include semiconductor dies stacked on top of each other. Each semiconductor die of the stack has a frontside facing toward the semiconductor wafer 102, which may be referred to as an active side of the semiconductor die having memory arrays, integrated circuits coupled to the memory arrays, bond pads coupled to the integrated circuits, etc., and a backside opposite to the frontside. In some embodiments, the semiconductor dies 104 may be stacked through a non-conductive film (NCF) underfill process. For example, solder bumps of an upper semiconductor die can be aligned with and attached to a through silicon via (TSV) of a lower semiconductor die for the solder-TSV bonding in each of the plurality of semiconductor die stacks 104. In this example, NCF underfill materials can be further flowed into the interface between the stacked semiconductor dies in a later process to provide electric isolation between the solder bumps and mechanical support between the stacked dies.

In some other embodiments, each of the plurality of semiconductor die stacks 104 may be stacked and processed through a non-NCF underfill process, e.g., direct bonding technologies including fusion bonding, covalent bonding, diffusion bonding, and/or thermal compression bonding (TCB). For example, a dielectric layer of the upper semiconductor die can be attached to a dielectric layer of the lower semiconductor die through forming covalent dielectric-dielectric bonds between the stacked semiconductor dies. Further, a metal bond pad of the upper semiconductor die can be attached to a metal bond pad of the lower semiconductor die through forming metal-metal diffusion bonds between the stacked semiconductor dies. In this example, the semiconductor dies of each of the semiconductor die stacks 104 are directly bonded to each other, without flowing NCF materials therebetween.

As shown in FIG. 1A, the CoW assembly including the plurality of semiconductor die stacks 104 and the semiconductor wafer 102 are attached to the carrier wafer 106 by the bonding layer 108. The bonding layer 108 may be made of adhesive materials and the carrier wafer 106 may be made of silicon. In some embodiments, the semiconductor wafer 102 may be processed in a laser grooving process before attaching the plurality of semiconductor die stacks 104 thereon. For example, electrical circuitries may exist on a top surface of the semiconductor wafer 102 for various applications. The electrical circuitries can extend across the singulation/scribe streets between the semiconductor dies 104 disposed above the top surface of the semiconductor wafer 102. In the present technology, these electrical circuitries are grooved, e.g., by a stealth dice through tape (SDTT) laser grooving process, away from the singulation/scribe streets on the top surface of the semiconductor wafer 102. This process can remove the electrical circuitries that restrict the expansion of each semiconductor assembly at the end of the semiconductor device assemblies process 100.

In the present technology, the spacer assembly 110 may be formed on a carrier wafer (not shown) and then implemented into the CoW assembly shown in FIG. 1A. Specifically, the spacer assembly 110 may be aligned to the spaces between each of the semiconductor dies 104 and inserted therein. The carrier wafer may be further released from the implemented spacer assembly 100. In some embodiments, the spacer assembly 100 is disposed in the center of spaces horizontally between the plurality of semiconductor die stacks 104 and does not completely fill out the spaces, leaving additional spaces between the sidewall of the spacer assembly 110 and the sidewall of the plurality of semiconductor die stacks 104. In some other embodiments, the spacer assembly 100 may be attached to the semiconductor wafer 102 by adhesive materials including adhesive paste, adhesive tape, etc. In particular, the spacer 112 can be attached to the semiconductor wafer 102 by a water-soluble resin, and the conductive package perimeter material can be held in the spacer 112 through pressure fitting.

FIG. 1B illustrates a cross-sectional view of the semiconductor device assemblies after a molding process. In this process, encapsulant materials, e.g., mold compound 116 can flow into the CoW assemblies and overflow above the top surface of the plurality of semiconductor die stacks 104 for packaging encapsulation. In particular, encapsulant materials, e.g., mold compound material or EMC, can be filled into the spaces of the semiconductor dies 104 through the additional spaces between the sidewall of the spacer assembly 110 and sidewall of each of the plurality of semiconductor die stacks 104. In this example, the mold compound can be made of materials including an epoxy-based liquid compound with granules, an epoxy-based liquid compound without granules, a granular compound, a thin-film based underfill, a thin-film based compound, a resin-based encapsulant, and/or a polymer.

In some embodiments, the plurality of semiconductor die stacks 104 are processed in a mold underfill (MUF) process, i.e., flowing mold encapsulating material into bond line thickness (BLT) between adjacent semiconductor die. In this example, the mold compound material 116 can flow vertically into the spaces between the spacer assembly 110 and the plurality of the semiconductor die stacks 104, and then laterally flow into the BLT between each of the stacked semiconductor dies 104. In addition, the mold encapsulating material may flow into the space between bottom dies of the plurality of semiconductor die stacks 104 and the semiconductor wafer 102. Here, the conductive package perimeter material 114 performs as a barrier to restrict the mold compound material from flowing out of the edge of the semiconductor wafer 102 and isolate the mold compound from the spacer 112.

In some other embodiments and as described earlier, the plurality of semiconductor die stacks 104 can be processed in a NCF underfill process. In this example, the BLT between each die of the stack of semiconductor dies 104 can be filled by nonconductive fill material. Moreover, the conductive package perimeter material 114 can perform as a stop to the non-conductive underfill material, which may horizontally squeeze out of the stack of semiconductor dies 104 during a thermal bonding process. In this example, the spacer assembly 100 including the conductive package perimeter material 114 may be attached on the semiconductor wafer 102 before the bonding of the plurality of semiconductor die stacks 104 there on.

As shown in FIG. 1B, the filling of mold compound 116 may continue until the mold compound layer is overflowed above the top surface of the plurality of semiconductor die stacks 104 and has a thickness close to 100 μm or more. The present technology increases the flexibility of using different encapsulant materials in the molding process. Specifically, encapsulant materials such as mold compound materials including epoxy-based liquid compound with granules, epoxy-based liquid compound without granules, granular compound, thin-film based underfill, thin-film based compound, resin-based encapsulant, and/or polymer that have various values of CTE can be implemented to the CoW assemblies descripted in this disclosure. In some embodiment and after filling the molding compound 116, the semiconductor device assemblies 100 may go through a PMC process at an elevated temperature, in which the molding material 116 are cured to have the mold compound fully cross-linked for stiffness.

Turning to FIG. 1C which illustrates a cross-sectional view of the semiconductor device assemblies 100 after a debonding process and a stealth dicing process. As shown, the carrier wafer 106 can be separated and removed away from the semiconductor wafer 102. The carrier wafer 102 debonding may be processed by a slide debonding technique, a laser debonding technique, a mechanical debonding technique, or a combination thereof. In addition, the debonding process may also include a cleaning process to remove the adhesive layer 108 disposed between the carrier wafer 106 and the semiconductor wafer 102. In some embodiments, the semiconductor device assemblies may be processed in a grinding process, e.g., a chemically mechanical polishing (CMP) process, to remove the carrier wafer 102 and the adhesive layer 108. The grinding process may stop at the semiconductor wafer 102.

Once the carrier wafer 106 is removed, the semiconductor device assemblies can be flipped upside down and processed by the stealth dicing technique. Specifically, a stealth laser can be applied on the semiconductor wafer 102 by aligning the laser spot to the spacer assembly 110. The stealth laser may be an infrared laser which could generate defects 118 through laser ablation within the semiconductor wafer 102 and above the spacer assembly 110. The defects 118 may include silicon dislocations, cracks, or a combination thereof. Further, the defects 118 may be through the thickness of the semiconductor wafer 102. In this process, the stealth laser can be controlled and focused through a conventional stealth dicing tool.

FIG. 1D illustrates a cross-sectional view of the semiconductor device assemblies 100 after a tape mounting process and mold grinding process. After the stealth dicing on the semiconductor wafer 102, the semiconductor device assemblies can be further flipped back and attached to a mount tape 120. In particular, the semiconductor wafer 102 can be attached to the mount tape 120 through an adhesive layer 122. In some embodiments, the adhesive layer 122 and the bonding layer 108 may be made of a same adhesive material.

Additionally, and as described in FIG. 1B, the mold compound 116 may completely fill out the spaces between each of the plurality of semiconductor die stacks 104 and overflow there above. The overflowed mold compound may form a layer above the plurality of semiconductor die stacks 104 with a thickness close to 100 μm or more. In this process, a grinding process, e.g., a CMP process, can be applied on the semiconductor device assemblies 100 to remove the overflowed mold compound layer. Specifically, the grinding process can stop at the plurality of semiconductor die stacks 104, i.e., exposing the top surface of each of the plurality of semiconductor dies 104. In this example, the overflowed mold compound layer 116 above the plurality of semiconductor die stacks 104 is completely removed in the grinding process so as to expose the top surface of the plurality of semiconductor die stacks 104 for heat dissipation. After the grinding process, the spacer assembly 110 may be coplanar to the top surface of the plurality of semiconductor die stacks 114. In some embodiments, the spacer assembly 110 may be less resistive to the grinding process and has a top surface slightly lower than the plurality of semiconductor die stacks 114. There may be mold residues disposed above the spacer assembly 110 after the grinding process. The mold residue, however, as described in later process of the semiconductor device assemblies, could break and be removed from the spacer assembly 110 and the semiconductor device assemblies 100.

In some embodiments, the semiconductor device assemblies may be mounted on the tape 120 before the stealth dicing process. For example, after the carrier wafer 106 is debonded and removed from the semiconductor wafer 102, the semiconductor device assemblies 100 may be mounted on the tape 120 by attaching the semiconductor wafer 102 and the mount tape 120 through the adhesive layer 108. After that, the stealth laser may be applied on the semiconductor wafer 102 through the mount tape 120. The stealth laser can be focused on the semiconductor wafer 102 and form defects therein through laser ablation. As described, the defects 118 can be aligned to and disposed above the spacer assembly 110. In addition, the defects 118 may be through the thickness of the semiconductor wafer 102.

FIG. 1E illustrates a cross-sectional view of the semiconductor device assemblies 100 after a heat expansion process and spacer removal process. As described, the spacer assembly 110 includes the spacer 112 and the conductive package perimeter material 114. In some embodiments, they can be made of materials having different coefficients of thermal expansion. For example, the spacer 112 can be PTFE with a CTE close to 127.6 ppm/° C. In contrast, the conductive package perimeter material can be made of copper having a lower CTE close to 16.7 ppm/° C. Here, the semiconductor device assemblies can be processed at an elevated temperature ranging from 200° C. to 500° C. The high temperature may be provided in a die to die separation tool. At the high process temperature, both of the spacer 112 and the conductive package perimeter material 114 of the spacer assembly 100 will expand at various rates, e.g., the spacer 112 expands more compared to the conductive package perimeter 114 because of the higher CTE of the spacer 112. In this example, the thermal expansion of the spacer 112 may cause cracks on the semiconductor wafer 102 through their interactions. Specifically, the cracks may be formed along the defects previously generated in the semiconductor wafer 102 in the laser stealth dicing process. As shown in FIG. 1E, the cracks may physically separate each of the semiconductor device assemblies.

During the heating process and as shown in FIG. 1E, the mount tape 120 may be stretched and the spacer 112 can be then removed from the semiconductor device assemblies 100. For example, the mount tape 120 can be stretched horizontally, along the direction 124 from a center to an edge of the mount tape 120. The stretching of the mount tape 112 assists separating the semiconductor wafer 102 into semiconductor dies (interface dies) 126 corresponding to each of the plurality of semiconductor die stacks 114 and forming individual semiconductor device assemblies. In addition, the stretching provides a lateral force to overcome the bonding between the spacer 112 and the conductive package perimeter material 114, assisting the removal of the spacer 112.

In some embodiments, the spacer 112 can be lifted up from the semiconductor device assemblies 100. For example, after the semiconductor wafer 102 is broken into semiconductor dies 126 due to the expansion of the spacer 112, the spacer 112 is exposed while the semiconductor dies 126 are being separated from the stretching of the mount tape 120. The spacer 112 can be then removed in a needle peeling process. In some other embodiments, the spacer 112 can be removed from the edge of the mount tape 112. For example, at the edge of the semiconductor wafer 102, there are no semiconductor dies 114 and the spacer 112 is in direct contact with the mold compound 116. After the separation of semiconductor device assemblies, the spacer 112 can be pulled out from the edge of the semiconductor wafer 102. In some other embodiments, the semiconductor device assemblies can be flipped upside down, having the plurality of semiconductor die stacks 114 and the spacer 112 disposed there between all face down. This way, the spacer 114 can fall off the semiconductor devise assemblies 100 automatically by the gravity.

In some embodiments, the spacer 112 can be removed in a plasma treatment or a wet cleaning process. For example, the spacer 112 may be made of an organic material. Once the semiconductor wafer 102 is broken into semiconductor dies 126 and each of the semiconductor device assemblies are separated, the spacer 112 can be removed in a plasma cleaning process. Specifically, oxygen plasma can be used to remove the organic spacer material through chemical reactions or physical sputtering of hydrocarbons. In another example, the spacer 112 can be made of water-soluble materials such as polymers, surfactants, or fibers. The water-soluble spacer material can be removed from the semiconductor device assemblies in a wet cleaning process using deionized water. Further, the spacer 112 can be made of a mold material. At the edge of the semiconductor wafer 102, the mold spacer may be attached with the mold encapsulating material 116. Once the semiconductor device assemblies are horizontally separated through stretching the mount tape, the spacer 112 maybe pulled out of the conductive package perimeter ring from the edge of the semiconductor wafer 102. Here, the gaps between the conductive package perimeter materials 114 that surround adjacent semiconductor die stacks 104 can relieve stresses formed in the PMC process to reduce the CoW assembly warpage, and further allow for an easy package separation between each of the semiconductor device assemblies 100.

In some embodiments and after the separation of the plurality of semiconductor die stacks 104 (including corresponding lower semiconductor dies 126), the semiconductor device assemblies 100 may go through the PMC process at an elevated temperature, in which the molding material 116 are cured to have the mold compound fully cross-linked for stiffness. Here, the gaps between the adjacent conductive package perimeter materials 114 of each of the semiconductor device assemblies 100 can relieve stress that is generated in the PMC process and reduce the CoW assembly warpage.

In the present technology, the CoW assembly warpage post encapsulation or the PMC process can be effectively controlled to be lower than a semiconductor manufacturing equipment tolerance on wafer warpage, e.g., below 1.0 mm, so that the CoW assembly wafers can be handled on equipments in downstream processes. The present technology may also eliminate the risk of polymer or encapsulation voids on the edge of each of the CoW assemblies. For example, encapsulate material can be filled to encapsulate the semiconductor die stack 104 and corresponding semiconductor die 126 of the CoW assembly. Specifically, encapsulate material can flow into the edge of each of the CoW assemblies to fill empty spaces that are available after the spacer 112 being removed.

Once the semiconductor wafer 102 is broken into semiconductor dies 126 and the spacer 112 are removed, the semiconductor wafer 102 can be processed in a singulation process to form separated semiconductor device assemblies 100. Specifically, the semiconductor wafer 102 can be sliced into individual semiconductor die for each of the semiconductor device assemblies 100 by singulating the semiconductor wafer 102 along gaps between the adjacent plurality of semiconductor die stacks 104. In some embodiment, the conductive package perimeter material 114 may form a conductive rectangular annulus that surrounds sidewalls of each of the semiconductor die stacks 104. Additionally, the conductive rectangular annulus of the conductive package perimeter material 114 may be disposed within each of the lower semiconductor dies 126 and has a footprint within a footprint of each of the lower semiconductor dies 126.

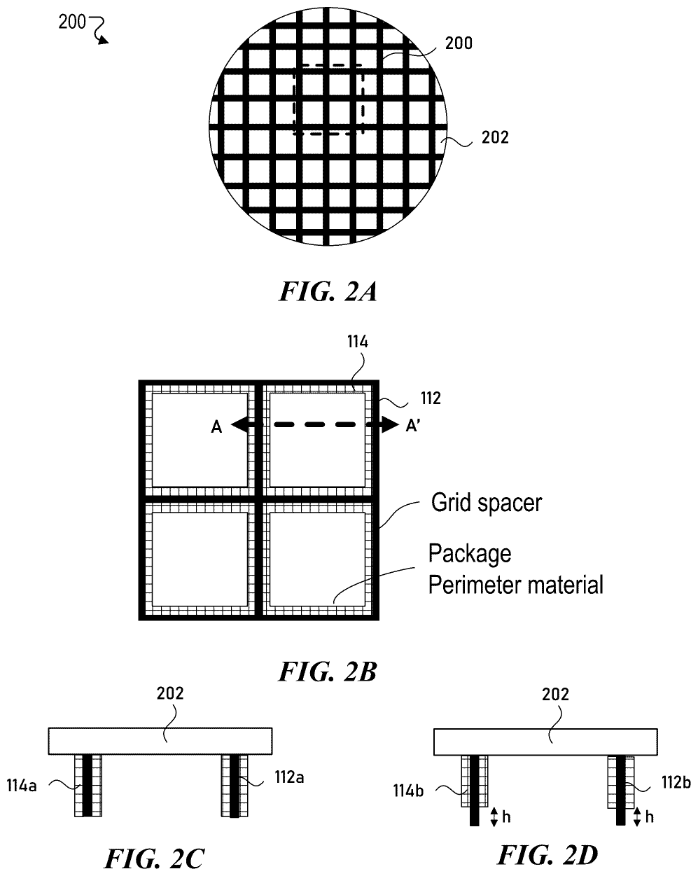

Turning to FIGS. 2A through 2D which depict a spacer assembly 200 for semiconductor device assemblies in accordance with embodiments of the present technology. FIG. 2A illustrates a top-down view of the spacer assembly 200 disposed on a carrier wafer 202. The carrier wafer 202 may be made of silicon or glass. Specifically, the spacer assembly can be attached to the carrier wafer 202 by adhesive materials. The carrier wafer 202 may be in various sizes including 6 inches, 8 inches, and 12 inches. In some embodiments, the carrier wafer 202 may have a same size to the semiconductor wafer 102 for the semiconductor device assemblies.

FIG. 2B reveals a zoomed in top-down view of the spacer assembly 200, which includes the spacer material 112 and conductive package perimeter material 114. As shown, the spacer material 112 is in a grid shape and having the conductive package perimeter material 114 disposed on grid spacer sidewalls. The spacer grid may be in square shape and expands across a top surface of the carrier wafer 202. In this configuration, the spacer material 112 may have a higher CTE than the conductive package perimeter material 114, allowing a pressure fitting of the conductive package perimeter material 114 within the spacer grid. Specifically, the conductive package perimeter material can be placed into the spacer grid at elevated temperatures wherein the spacer grid expands. When it cools down, the spacer material 112 will shrink and the conductive package perimeter material 114 can be then fitted within each of the spacer grids and held rigidly by the pressure of the spacer material 112. Notably, at the edge of the carrier wafer 202, the spacer material 112 is exposed and does not hold any conductive package perimeter material 114 on its sidewalls.

In some embodiments, the spacer material 112 may be attached to the carrier wafer 202 by a water-soluble resin. Moreover, the spacer material 112 may have a low surface energy that prevents molding compounds or epoxy encapsulants from sticking on the spacer for reusage. Further, the spacer grid may have a thickness ranging from 20 μm to 340 μm, depending on the dicing scribe width. As described, the spacer 112 may be made of at least one of polytetrafluoroethylene (PTFE), organic materials, water-soluble materials, and/or molding materials.

In some embodiments, the conductive package perimeter material 114 may have a thickness ranging from 100 μm to 200 μm. As shown in FIG. 2B, semiconductor dies can be disposed within the spacer grid following processes described through FIGS. 1A to 1E. Here, the conductive package perimeter material 114 sits in the semiconductor die edge to package edge (DE2PE) region which typically ranges from 200 μm to 300 μm. The thickness of the conductive package perimeter material 114 is configured to be less than the DE2PE length to allow mold compound filling into between the semiconductor dies 114 and the conductive package perimeter material 114. As described, the conductive package perimeter material 114 may be made of conductive metals including copper, tungsten, molybdenum, nickel, titanium, tantalum, platinum, silver, gold, ruthenium, iridium, rhenium, rhodium, or alloys thereof.

Turning to FIGS. 2C and 2D, which illustrate cross sectional views of the spacer assembly 200 along the A-A′ plane shown in FIG. 2B. In some embodiments, the spacer 112 and the conductive package perimeter 114 are coplanar in the spacer assembly 200. For example and as shown in FIG. 2C, spacer 112a has a height similar to the conductive package perimeter material 114a. In this example, the spacer material 112a may be firstly attached to the carrier wafer 202 in a grid shape. At an elevated temperature, the spacer material 112a expands and the conductive package perimeter 114a is further disposed on the carrier wafer 202 and adjacent to each of the expanded spacer grids. After the temperature cools down, the conductive package perimeter material 114a is securely held in the spacer grid of the spacer assembly 200 through pressure fitting. As described, the conductive package perimeter material 114a may have a CTE lower than the spacer material 112. To achieve a planar surface there between, the conductive package perimeter material 114a may be slightly lower than the spacer material 112a, e.g., by 1 μm to 3 μm. Therefore, both of the spacer material 12a and the conductive package perimeter material 114a end up having the same height after the temperature cools down.

In some other embodiments, the spacer material 112 and the conductive package perimeter material 114 are not coplanar in the spacer assembly 200. For example and as shown in FIG. 2D, the height of the conductive package perimeter material 114b is lower than the spacer material 112b by a tolerance height h close to 25 μm. At an elevated temperature, once the spacer grid 112b is attached to the carrier wafer 202, the conductive package perimeter material 114b can be further disposed in each of the spacer grids. Specifically, the conductive package perimeter material 114b may have a height lower than the spacer grid 114b by a value close to or slightly lower than the tolerance height h.

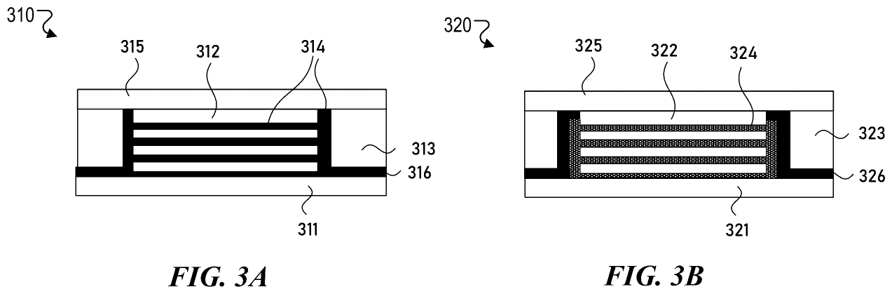

FIGS. 3A through 3B illustrates semiconductor device assemblies having a gap between conductive package perimeter material and interface die in accordance with embodiments of the present technology. In particular, the spacer assembly described in FIG. 2D can be implemented in the semiconductor device assemblies illustrated here in FIGS. 3A and 3B. FIG. 3A illustrates a cross-sectional view of the semiconductor device assembly 310 formed through the processes described in FIGS. 1A through 1E. Specifically, the semiconductor device assembly 310 is fabricated through a non-NCF underfill process, e.g., a MUF process. As shown, the semiconductor device assembly 310 includes a stack of semiconductor dies 312 disposed on a lower semiconductor die 311. The semiconductor device assembly 310 includes conductive package perimeter material 313 that is vertically aligned and surrounding the stack of semiconductor dies 312. In addition, the semiconductor device assembly 310 includes a flat thermal interface layer 315 disposed above a top die of the stack of semiconductor dies 312 and the conductive package perimeter material 313. The thermal interface layer 315 may be configured for heat dissipation and electromagnetic interference (EMI) shielding for the semiconductor device assembly 310. Further, the lower semiconductor die 311 may be formed from a semiconductor wafer on which the stack of semiconductor dies 312 are attached. As described in FIG. 1E, the semiconductor wafer may break into interface dies at an elevated temperature due to an expansion of a spacer grid.

In this example, mold compound material 314 can flow into the semiconductor device assembly 310 through the gap between the stack of semiconductor dies 312 and the conductive package perimeter material 313. Specifically, the mold compound 314 can flow into the BLT between each die of the stack of semiconductor dies 312. Moreover, the mold compound material 314 can horizontally flow into the gap 316 disposed between the conductive package perimeter material 313 and the lower semiconductor die 311. The gap 316 is formed due to a height variance h between the conductive package perimeter material 313 and a spacer used to form the semiconductor device assembly 310. In this example, the spacer assembly, specifically the package perimeter material 313 can be bonded on the lower semiconductor die 311 after the stack of semiconductor dies 312 being attached on the lower semiconductor die 311.

FIG. 3B illustrates a cross sectional view of another semiconductor device assembly 320 formed through the processes described in FIGS. 1A through 1E. Similarly, the semiconductor device assembly 320 includes a stack of semiconductor dies 322 disposed on a lower semiconductor die 321, a conductive package perimeter material 323 vertically aligned and surrounding the semiconductor dies 322, and a thermal interface layer 325 disposed above the semiconductor dies 322 and the conductive package perimeter material 323. The semiconductor device assembly 320 also includes a gap 326, which is vertically disposed between the stack of semiconductor dies 322 and the conductive package perimeter material 323 and horizontally disposed between the conductive package perimeter material 323 and the lower semiconductor die 321.

In some embodiments, the semiconductor device assembly 320 is processed through the NCF underfill process. For example, each of the semiconductor dies 322 may be vertically stacked through solder-TSV bonds and the BLT is filled by the nonconductive fill material 324. In this example, the stack of semiconductor dies 322, together with nonconductive fill material 324 disposed in the BLT between the semiconductor dies 322, can be attached on the lower semiconductor die 321 after the spacer assembly (e.g., the package perimeter material 323) being bonded on the lower semiconductor die 321. During the thermal bonding of the semiconductor dies 322 to the lower semiconductor die 321, the nonconductive fill material may horizontally squeeze out of the BLT regions, as shown in FIG. 3B. In this example, molding material 326 can be filled into the semiconductor device assembly 320 through the gap disposed between the stack of semiconductor dies 322 and the conductive package perimeter material 323. As shown, the vertically aligned molding material 326 isolates the stack of semiconductor dies 322, specifically squeezing out nonconductive fill material 324, from the conductive package perimeter material 323. In some embodiments, the squeezing out nonconductive fill material 324 can be in contact with the conductive package perimeter material 323. Here, the nonconductive fill material 324 can neither overflow out of the semiconductor device assembly 320 nor expose to the edge of the semiconductor device assembly 320 because of the surrounding conductive package perimeter material 323 of the spacer grid which performs as a stop to the nonconductive fill material 324. In addition, the gap 326 disposed between the conductive package perimeter material 323 and the lower semiconductor die 321 can also be filled by molding material. In some other embodiments, the nonconductive fill material 324 squeezing out of the BLT regions may be discontinuous along the vertical sidewall of the stack of semiconductor dies 322.

The gaps 316 and 326 of the semiconductor device assemblies 310 and 320 can mechanically separate the conductive package perimeter materials 313 and 323 from the lower semiconductor dies 311 and 321, respectively. At an elevated temperature during the processing and operating of the semiconductor device assemblies, there is a risk of breaking the interface dies by the conductive package perimeter material due to different CTEs there between. The gaps 316 and 326 included in the semiconductor device assemblies 310 and 320 may effectively reduce the risk of interface dies cracking due the CTE mismatch. Further, the gaps 316 and 326 can provide electrical isolation between the conductive package perimeter materials (e.g., 313 and 323) and the interface dies (e.g., 311 and 321), respectively.

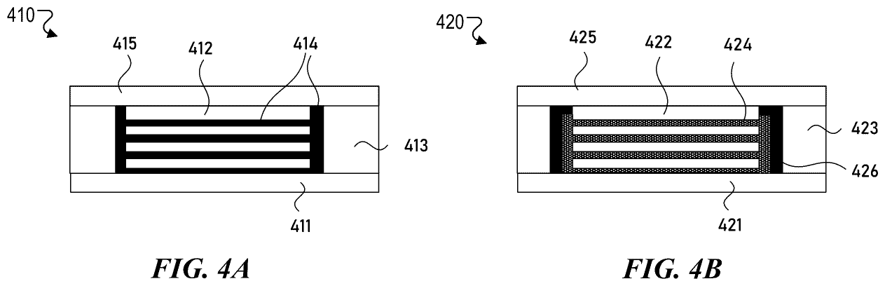

FIG. 4A through 4B illustrate semiconductor device assemblies 410 and 420 having a conductive package perimeter material directly disposed on an interface die in accordance with embodiments of the present technology. In particular, the spacer assembly described in FIG. 2C can be implemented in the semiconductor device assemblies illustrated here in FIGS. 4A and 4B. FIG. 4A illustrates a cross-sectional view of the semiconductor device assembly 410 formed through the processes described in FIGS. 1A through 1E. Specifically, the semiconductor device assembly 410 is fabricated through the MUF underfill process. As shown, the semiconductor device assembly 410 includes a stack of semiconductor dies 412 disposed on a lower semiconductor die 411. The semiconductor device assembly 410 also includes a conductive package perimeter material 413 disposed on the lower semiconductor die 411 and surrounding the stack of semiconductor dies 412. Above the semiconductor dies 412 and the conductive package perimeter 413, a thermal interface layer 415 is disposed for heat dissipation and EMI shielding of the semiconductor device assembly 410.

In this example, a mold compound material 414 can flow into the semiconductor device assembly 410 through a gap between the stack of semiconductor dies 412 and the conductive package perimeter material 413. Additionally, the mold compound material 414 can flow into the BLT between each of the stack of semiconductor dies 412. As shown, the conductive package perimeter material 413 directly contacts the lower semiconductor die 411 and the mold compound material 414 is limited in the BLT and gaps between the semiconductor dies 412 and the conductive package perimeter material 413.

FIG. 4B illustrates a cross-sectional view of the semiconductor device assembly 420. Similar to the semiconductor device assembly 410, the semiconductor device assembly 420 includes a stack of semiconductor dies 422 disposed on a lower semiconductor die 421, a conductive package perimeter material 423 disposed on the lower semiconductor die 421 and surrounding the semiconductor dies 422, and a thermal interface layer 425 disposed above the stack of semiconductor dies 422 and the conductive package perimeter material 423. In this example, the stack of semiconductor dies 422 is processed through a NCF underfill process, e.g., flowing nonconductive fill material 424 into BLT between each of the stack of semiconductor dies 422. In this example, the spacer grid including the conductive package perimeter material 423 can be attached on the bottom semiconductor die 412 before attaching the stack of semiconductor dies 422 there on. Further, the semiconductor device assembly 420 includes a gap vertically disposed between the stack of semiconductor dies 422 and the conductive package perimeter material 423. The gap can be filled by molding material 426. As shown in FIG. 4B, the nonconductive fill material 424 squeezing out of the semiconductor dies 422 during the thermal bonding process can be stopped by the surrounding conductive package perimeter material 423 and limited within the semiconductor device assembly 420. Specifically, the molding material 426 can be filled in the gap once the stack of semiconductor dies 422 and the conductive package perimeter material 423 are attached to the lower semiconductor die 421. In some other embodiments, the nonconductive fill material 424 squeezing out of the BLT regions may be discontinuous along the vertical sidewall of the stack of semiconductor dies 422.

In the present technology, the heat transfer of the CoW assemblies can be enhanced through the conductive package perimeter material. For example, heat generated from the semiconductor die stacks 322 and 422 can be respectively transferred out through the conductive package perimeter material 323 and 423 disposed at the edge of the CoW assemblies. In addition, the heat generated from the semiconductor dies (interface dies) 411 and 421 can be transferred out through the conductive package perimeter materials 413 and 423, respectively as they are directly contacted as shown in FIGS. 4A and 4B.

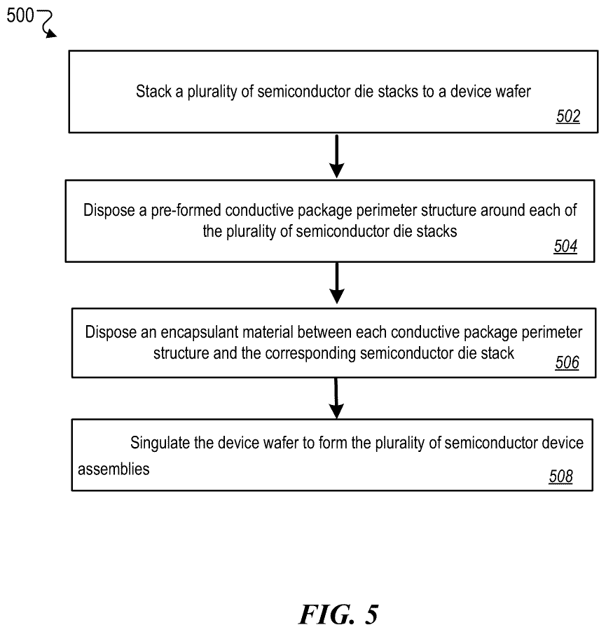

FIG. 5 is a flow chart illustrating a method 500 of processing the semiconductor device assemblies according to embodiments of the present technology. The method 500 includes stacking a plurality of semiconductor die stacks to a device wafer, at 502. For example, the plurality of semiconductor die stacks 104 can be stacked to the semiconductor wafer 102, as shown in FIG. 1A. Specifically, a bottom die of each of the plurality of semiconductor die stacks 104 can be attached on the semiconductor wafer 103 through a direct bonding technology or a solder-TSV bonding technology with an interface.

The method 500 also includes disposing a pre-formed conductive package conductive package perimeter structure around each of the plurality of semiconductor die stacks, at 504. For example, the pre-formed spacer assembly 110 can be disposed on the semiconductor wafer 102 and around each of the plurality of semiconductor die stacks 104. In particular, the spacer assembly 110 includes the package conductive package perimeter material 114 that is disposed around each of the semiconductor die stacks 104, as shown in FIG. 1A.

Further, the method 500 includes disposing an encapsulant material between each conductive package perimeter structure and the corresponding semiconductor die stack, at 506. For example, mold compound material 116 can flow into a gap between each of the plurality of semiconductor die stacks 104 and adjacent package conductive package perimeter mater 114 of the spacer assembly 110. For semiconductor die stacks 104 having empty interfaces between vertically stacked semiconductor dies, the mold compound material 116 can further flow into the interface between stacked semiconductor dies.

Lastly, the method 500 includes singulating the device wafer to form the plurality of semiconductor device assemblies, at 508. For example, after the semiconductor wafer 102 is broken into semiconductor dies 126, the spacer 112 of the spacer assembly is lifted out, as shown in FIG. 1E. Further, the semiconductor wafer 102 is singulated along the gaps between neighboring semiconductor die stacks 104 to form the plurality of semiconductor device assemblies 100.

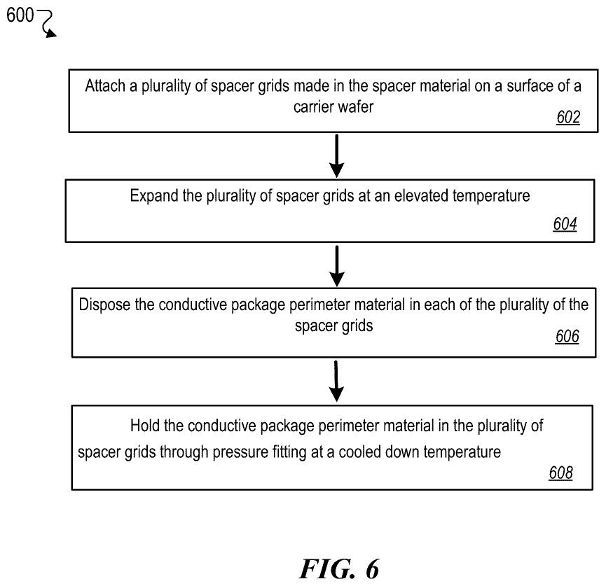

Turning now to FIG. 6 which is a flow chart illustrating a method 600 of processing a spacer assembly according to embodiments of the present technology. The method 600 includes attaching a plurality of spacer grids made in the spacer material on a surface of a carrier wafer, at 602. For example, as shown in FIG. 2B, the spacer material 112 can be formed in a grid shape and is attached to the top surface of the carrier wafer 202. Specifically, the spacer 112 may be made of a material having a higher CTE, e.g., PTFE.

The method 600 also includes expanding the plurality of spacer grids at an elevated temperature, at 604. For example, once the spacer grid 112 is attached to the carrier wafer 202, it may be processed at an elevated temperature ranging from 200° C. to 500° C. Here, the spacer grid 112 will expand at the elevated temperature due to its high CTE.

In addition, the method 600 includes disposing the conductive package perimeter material in each of the plurality of the spacer grids, at 606. For example, the conductive package perimeter material 114 can be disposed into the spacer grid 112, e.g., on the sidewall of the spacer grid 112. Here, the conductive package perimeter material 114 may be made of materials having a lower CTE, e.g., copper.

Further, the method 600 includes holding the conductive package perimeter material in the plurality of spacer grids through pressure fitting at a cooled down temperature, at 608. For example, as described in FIG. 2B, the spacer assembly 200 can be processed at a cooled down temperature, shrinking both of the spacer material 112 and the conductive package perimeter material 114. Here, the shrinkage of the conductive package perimeter material 114 is less than that of the spacer material 112. As a result, the conductive package perimeter material 114 can be fitted within each of the spacer grids 112 and held rigidly therein through the pressure fitting.

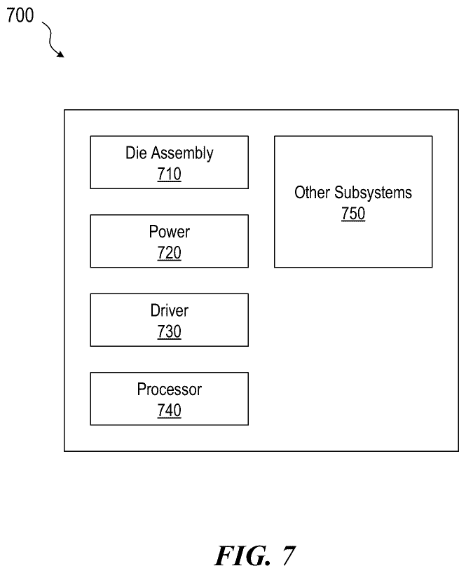

Any one of the semiconductor structures described above with reference to FIGS. 1A-4B can be incorporated into any of a myriad of larger and/or more complex systems, a representative example of which is system 700 shown schematically in FIG. 7. The system 700 can include a semiconductor device 710, a power source 720, a driver 730, a processor 740, and/or other subsystems or components 750. The semiconductor device 710 can include features generally similar to those of the semiconductor devices described above, and can therefore include the CoW assemblies and the spacer grid described in the present technology. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, and appliances. Components of the system 700 may be housed in a single unit or distributed over multiple, interconnected units (e.g., through a communications network). The components of the system 700 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (Fe RAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a lower semiconductor die;
a stack of upper semiconductor dies disposed over the lower semiconductor die;
a conductive package perimeter material surrounding the stack of upper semiconductor dies; and
an encapsulant material disposed between sidewalls of the stack of upper semiconductor dies and the conductive package perimeter material, and horizontally extending between the conductive package perimeter material and the lower semiconductor die.

2. The semiconductor device assembly of claim 1, wherein the encapsulant material electrically isolates the conductive package perimeter material from the stack of upper semiconductor dies and the lower semiconductor die.

3. The semiconductor device assembly of claim 1, further including a thermal interface layer disposed above the stack of upper semiconductor dies and the conductive package perimeter material.

4. The semiconductor device assembly of claim 1, wherein the conductive package perimeter material comprises copper, silver, gold, nickel, tungsten, or a combination thereof.

5. The semiconductor device assembly of claim 1, wherein the conductive package perimeter material is configured to provide electromagnetic interference (EMI) shielding for the semiconductor device assembly.

6. The semiconductor device assembly of claim 1, wherein a top surface of the stack of upper semiconductor dies and a top surface of the conductive package perimeter material are coplanar.

7. The semiconductor device assembly of claim 1, wherein the encapsulant material is a molding compound including at least one of an epoxy-based liquid compound with granules, an epoxy-based liquid compound without granules, a granular compound, a thin-film based underfill, a thin-film based compound, a resin-based encapsulant, or a polymer.

8. A semiconductor device assembly, comprising:
a lower semiconductor die;
a stack of upper semiconductor dies disposed over the lower semiconductor die;
a conductive rectangular annulus surrounding sidewalls of the stack of upper semiconductor and having a footprint within a footprint of the lower semiconductor die; and
an encapsulant material electrically isolating sidewalls of the stack of upper semiconductor dies from the conductive rectangular annulus, and electrically isolating the conductive rectangular annulus from an upper surface of the lower semiconductor die.

9. The semiconductor device assembly of claim 8, further includes a thermal interface layer disposed above the stack of upper semiconductor dies and the conductive rectangular annulus.

10. The semiconductor device assembly of claim 8, wherein a top surface of the stack of upper semiconductor dies and a top surface of the conductive rectangular annulus are coplanar.

11. The semiconductor device assembly of claim 8, wherein the conductive rectangular annulus comprises copper, silver, gold, nickel, tungsten, or a combination thereof.

12. A method of forming a plurality of semiconductor assemblies, comprising:
stacking a plurality of semiconductor die stacks to a device wafer;
disposing a pre-formed spacer assembly structure including a spacer material and a conductive package perimeter material around each of the plurality of semiconductor die stacks;
disposing an encapsulant material between the conductive package perimeter material of the pre-formed spacer assembly structure and the corresponding semiconductor die stack; and
singulating the device wafer to form the plurality of semiconductor device assemblies.

13. The method of claim 12, further comprises disposing the encapsulant material between semiconductor dies of each of the plurality of semiconductor die stacks.

14. The method of claim 12, wherein the pre-formed conductive package perimeter structure is formed by:
attaching a plurality of spacer grids made in the spacer material on a surface of a carrier wafer;
expanding the plurality of spacer grids at an elevated temperature;
disposing the conductive package perimeter material in each of the plurality of the spacer grids; and
holding the conductive package perimeter material in the plurality of spacer grids through pressure fitting at a cooled down temperature.

15. The method of claim 14, wherein the spacer material can be made of at least one of polytetrafluoroethylene (PTFE), organic materials, water-soluble materials, and/or molding materials.

16. The method of claim 15, wherein the spacer material has a coefficient of thermal expansion (CTE) higher than the conductive package perimeter material.

17. The method of claim 14, further includes:
stealth dicing on the device wafer to form dislocations aligned with the plurality of the spacer grids of the pre-formed spacer assembly structure;
heating the plurality of semiconductor assemblies in an elevated temperature to expand the conductive package perimeter material to interact with the device wafer; and
stretching the device wafer to form lower semiconductor dies that each corresponds to one of the plurality of semiconductor assemblies.

18. The method of claim 14, further includes removing the plurality of spacer grids from the semiconductor assemblies through at least one of lifting up the spacer material from the semiconductor assemblies, removing exposed spacer material from an edge of the device wafer, and/or rotating the plurality of semiconductor assemblies upside down.

19. The method of claim 12, further comprises grinding overflowed encapsulating material disposed above the conductive package perimeter structure and the plurality of semiconductor die stacks to expose front surfaces of top semiconductor dies of the plurality of semiconductor die stacks, wherein a top surface of the stack of upper semiconductor dies and a top surface of the conductive package perimeter material are coplanar.

20. The method of claim 12, further includes forming a thermal interface layer above the stack of semiconductor dies and the conductive package perimeter material in each of the plurality of semiconductor device assemblies.
